(19) United States
(12) Patent Application Publication
(10) Pub. No.: US 2008/0054970 A1
(43) Pub. Date: Mar. 6, 2008

(54) Voltage conveyor for changing voltage levels in a controlled manner

(75) Inventors: Anthony E. Turvey, Reading, MA (US); Chris McQuilkin, Salem, NH (US)

Correspondence Address: BROMBERG & SUNSTEIN LLP, 125 SUMMER STREET, BOSTON, MA, 02110-1618, US

(73) Assignee: Analog Devices, Inc.

(21) Appl. No.: 11/513,627

(22) Filed: Aug. 31, 2006

(51) Int. Cl. H03K 5/12

(52) U.S. Cl. 327/170

(57) ABSTRACT

A system for changing voltage states at an output of an electronic device. In one embodiment, the system includes a voltage conveyor module coupled to the output of the electronic device and a voltage signal generator capable of producing a first voltage at the output. The voltage conveyor module is controllably coupled to the output, and the voltage signal generator is controllably uncoupled from the output of the electronic device. The voltage conveyor conveys the second voltage to the output in a characteristic manner. The second voltage level is provided as input to the voltage signal generator and the voltage signal generator is recoupled to the output of the electronic device. The voltage conveyor is then electrically uncoupled from the output. The voltage conveyor may control the voltage transition such that the voltage transitions without discontinuities. In other embodiments, the voltage may transition monotonically. In yet other embodiments, the voltage transitions so as to avoid overshoot, undershoot, or preshoot. The voltage conveyor may also be slew rate limited, and operate in a high voltage mode beyond the normal operating of the voltage signal generator.

### TECHNICAL FIELD AND BACKGROUND ART

The present invention relates to transitions between voltage levels and more specifically for transitioning between voltage levels in a controlled manner.

Integrated circuits, such as flash memory, are tested using automatic test equipment (ATE) to confirm their operating characteristics. The tested devices are generally known by those of ordinary skill in the art as Devices Under Test or “DUTs.” Automatic Test equipment includes an ATE integrated circuit having pin electronics. The pin electronics may have a DCL (driver, comparator, and load). ATE integrated circuits are designed for testing specific conditions (i.e. voltage range) of one or more DUTs and are designed to test other integrated circuits at a certain speed (tests/sec.). In designing the ATE integrated circuit, the designer must weigh the voltage range against the ATE integrated circuit's operational speed and precision. For example, a comparator on the ATE integrated circuit should be capable of operating in the 100 MHz to the GHz range and transition between a low to high signal within about 100 pico-seconds to a few nano-seconds and operate with signals between −2V and +7V. As a result, at present, ATE integrated circuits generally have a testing range between −2V and +7V to accommodate the voltage levels of the integrated circuits being tested. Extending the voltage range above +7V has a significant effect on the choice of fabrication technology, and has a direct tradeoff against the integrated circuit's operational speed and precision.

When flash memory devices are tested, a signal level is generally used that remains within the −2V to +7V operational voltage range of the tester. But in addition, the flash memory requires a high voltage (typically +13V) at one of the pins to change the state of the flash memory to a special programming or diagnostic state.

When the driver of the ATE integrated circuit is used for testing the DUT, the output resistance of the ATE integrated circuit should be matched to the impedance of the transmission line connecting to the DUT to avoid signal losses and preserve timing accuracy. In attempting to design a system that can accommodate both the low and high voltage levels on a single integrated circuit, prior art designers have used MOSFET switches to switch between the low voltage signals of the pin electronics and the high voltage signals of a high voltage buffer. This prior art design is limited in performance because of the inherent resistive variations in MOSFET switches due to manufacturing techniques. In order to tightly control MOSFET switch resistance it is necessary to make the switch very large. This in turn makes the capacitance of the switch prohibitive to achieving high speed test performance. When the switch is made adequately small, the mismatch in resistance between the output of the ATE integrated circuit and the input impedance of the transmission line connecting to the DUT causes significant errors due to transmission line reflections.

In order to accommodate both the low voltage and high voltage test signals, designers of prior art systems have resorted to constructing two separate integrated circuits (pin electronics 12 and high voltage buffer 11) that are switched by a mechanical or optically controlled relay 10 as shown in FIG. 1. Because of the size of the relay 10, which can be much larger than the integrated circuit, the resistance produced by the relay 10 can be replicated during production, and therefore accurately accounted for so that the overall output resistance can be reliably matched to the transmission line. But the capacitance of the relay switch is large, and this again has an adverse impact on tester speed.

Because the prior art test equipment design includes two integrated circuits (11, 12) and a relay, the size of the circuitry is more than double that of a typical ATE design. The size increase is especially disadvantageous in the case of flash memory testing, since ATE systems generally test hundreds to thousands of integrated circuits simultaneously where each tested integrated circuit requires a separate channel including the two integrated circuits and relay. Therefore, it is desirable to minimize silicon area in ATE systems.

In addition to requiring the high voltage signal, flash memory manufacturers require that the high voltage signal transition to and from the low voltage signal range in a monotonic manner with a specified slew rate and minimal overshoot, to avoid problems that may otherwise result with certain flash memory devices.

### SUMMARY OF THE INVENTION

Systems and methods for changing voltage states at an output of an electronic device are disclosed. In one embodiment, the system includes a voltage conveyor module controllably coupled to the output of the electronic device, a first voltage source and a second voltage source producing a first voltage and a second voltage respectively and a voltage signal generator capable of producing at least the first voltage at the output. The voltage conveyor module is controllably coupled to the output and conveys the second voltage to the output in a controlled manner. The voltage conveyor may be controllably coupled through an external or internal switching structure. The switching structure may include a high impedance mode of operation for decoupling the voltage conveyor from the output of the electronic device. The voltage conveyor may control the voltage transition such that it occurs without discontinuities. In other embodiments, the voltage may transition monotonically. In yet other embodiments, the voltage transitions so as to avoid overshoot, undershoot, or preshoot. The voltage conveyor may also be slew rate limited. In certain embodiments, the first and second voltage sources are controllably coupled to an input of the voltage signal generator. In other embodiments, there are three or more voltage sources that are selectable and may be provided to the voltage signal generator. In other embodiments, each voltage source is associated with a separate voltage signal generator.

In yet other embodiments, the voltage signal generator is cable of operation within a given voltage range. In such an embodiment, the first voltage may be within the voltage range of operation and the second voltage may be outside of the voltage signal generator's range of operation.

The system can be constructed on a single integrated circuit and the integrated circuit can be used in automatic testing equipment. In such an embodiment, the voltage signal generator is a pin electronics circuit. Pin electronics can include a comparator, a load, a driver, and a parametric measurement unit. In testing circuits, such as flash memory, the tested circuit or device under test (DUT) may require a plurality of test voltage levels. In such embodiments, the voltage conveyor may have a supply rail voltage that is greater than the supply rail voltage of the pin electronics circuit.

In order to prevent damage to the pin electronics circuitry, the system can include a high voltage sensor that senses the voltage at the DUT pin. When the voltage exceeds the supply rail voltage of the pin electronics circuit, the high voltage sensor causes the supply rail voltage of the pin electronic circuit to increase. The pin electronics may be constructed as a main stage and an output stage. In such a configuration, the high voltage sensor would control only the voltage supply rails of the output stage.

Both the voltage conveyor and the voltage signal generator include a switching structure that creates a high impedance that effectively disconnects the circuitry from the output. The switching structure can be a physical switch, a MOSFET, or circuitry that causes a high impedance state. For example, if the circuitry includes controllable current sources, the current sources may be turned off thereby causing the circuitry to exhibit a high impedance.

The voltage conveyor can be switchably coupled to a plurality of input voltages, thus allowing for switching between the plurality of voltages. In certain embodiments, the input voltages are provided by the pin electronics.

Also disclosed is a method for switching between voltage levels of a circuit. For example, the voltage levels may be switched in a controlled manner for testing an integrated circuit having at least one pin. In certain embodiments, the integrated circuit being tested has a first voltage range of operation and a second voltage range of operation greater than the first range of operation. A tester integrated circuit provides a first voltage signal having a first voltage level within the first range of operation to a pin of the integrated circuit being tested. The tester integrated circuit slews the voltage at the pin of the integrated circuit to a second voltage level in the second range of operation using the tester integrated circuit. The tester integrated circuit includes at least two circuits, a first circuit and a second circuit. The first circuit provides the first voltage to the integrated circuit being tested. The second circuit is switchably coupled to the integrated circuit being tested and slews the voltage at the pin of the integrated circuit being tested to the second voltage. The first circuit is electrically disconnected from the pin of the integrated circuit being tested. The first circuit is then presented with the second voltage signal and is electrically reconnected to the integrated circuit being tested.

The second circuit of the tester integrated circuit may be a buffer and can include an operational amplifier. This second circuit is a voltage conveyor circuit that is switchably connected to the output/pin of the device being tested. The voltage conveyor allows the transition of the voltage levels at the pin of the device being tested to transition in a monotonic fashion. The voltage conveyor can be switched out of the signal path and a voltage signal generator can be switched into the path.

Although the methodology disclosed is described with respect to the testing of integrated circuits, the methodology is equally applicable in other environments where a controlled transition between two voltage levels is desired.

### BRIEF DESCRIPTION OF THE DRAWINGS

The foregoing features of the invention will be more readily understood by reference to the following detailed description, taken with reference to the accompanying drawings, in which:

FIG. 1 is a prior art system for providing both a low voltage and a high voltage to a device under test using a relay;

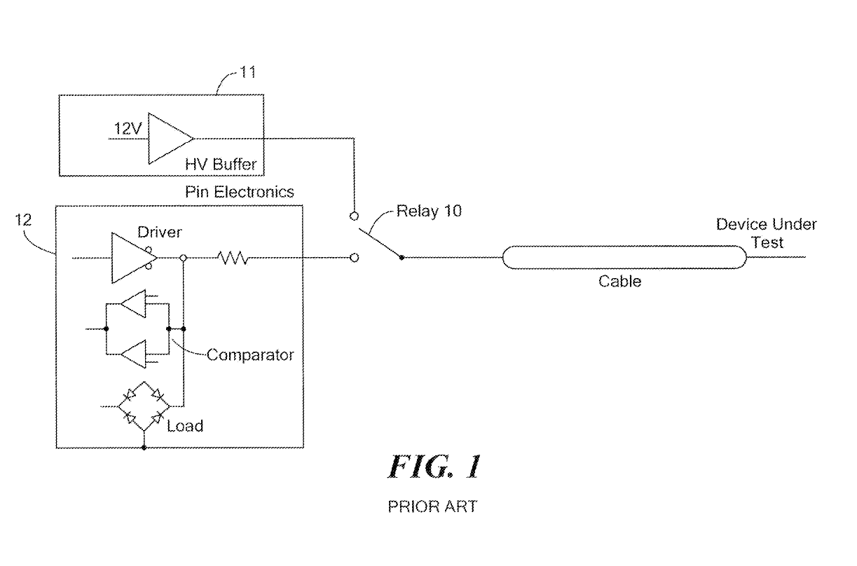

FIG. 2 shows a schematic of one embodiment of the invention;

FIG. 3 shows a schematic adding additional circuitry for adjusting the supply rail voltages;

FIG. 4 is circuit schematic of one embodiment of the invention that allows for the switching between a first input having a first voltage level and a second input having a second voltage level without any voltage glitches occurring due to the change in voltage states; and

FIG. 5 is a flow chart describing the process of switching between a first voltage level and a second voltage level without any voltage glitches.

### DETAILED DESCRIPTION OF SPECIFIC EMBODIMENTS

Definitions. As used in this description and the accompanying claims, the following terms shall have the meanings indicated, unless the context otherwise requires: the term “voltage conveyor” and “buffer” shall refer to any device having an associated slew rate that includes an input for receiving a voltage and produces a voltage at an output. The term “voltage signal generator” means an electrical device that is capable of providing at its output a voltage of a predetermined value. The term “controllably coupled” shall refer to the ability to selectively couple a device to an electronic circuit by providing a control signal. The term “voltage source” refers to an electrical device that produces a voltage.

Embodiments of the invention teach integrating a low voltage circuit and a high voltage circuit on the same integrated circuit. Such an integrated circuit may be used in automatic test equipment (ATE) for testing devices, such as flash memory that include a high voltage pin that changes the mode of operation of the device under test (DUT). Although the disclosure often references ATE for its examples, the system and methodology may be employed when a controlled voltage transition is desired between a plurality of voltage states.

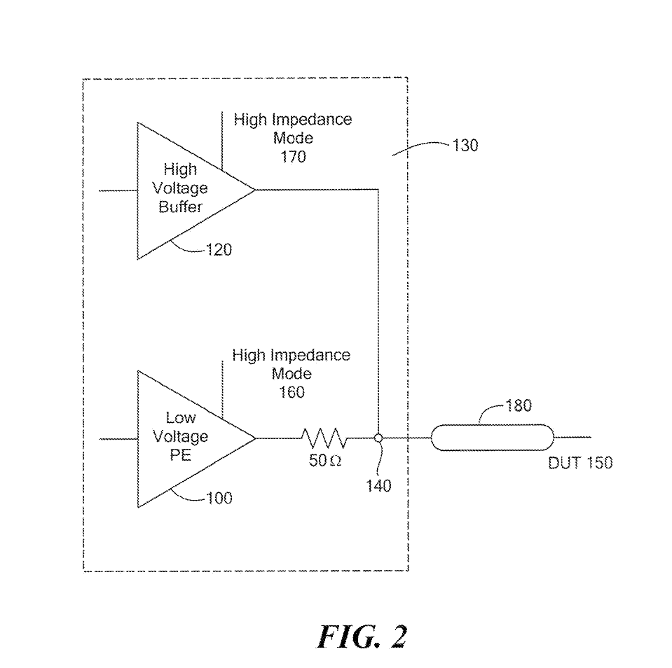

FIG. 2 shows a schematic of one embodiment of the invention. In this embodiment, low voltage pin electronics 100 (having low voltage level supply rail voltages e.g. −5V and +10V) and a high voltage buffer circuit 120 (having a higher voltage level supply rail voltages than the low voltage pin electronics e.g. −5V and +17V) are integrated on to a single integrated circuit 130. The pin electronics and the high voltage buffer may be manufactured using the same processing steps and are formed on the same silicon wafer. By implementing both the pin electronics and high voltage buffer circuits on the same silicon wafer, the overall test circuit size can be minimized.

The pin electronics circuit 100 may include one or more of the following components: a comparator, a driver, and a load circuit (not shown). Pin electronics, as the term is understood in the art, may also include additional circuitry (not shown in FIG. 2), such as a parametric measurement unit (PMU). In one example, the low voltage pin electronics may output high speed signals between −2V and +7V whereas, the high voltage buffer and PMU produces low speed voltage signals between −2V and +13V.

The pin electronics and the high voltage buffer are electrically connected at an output pin 140. The device under test 150 attaches to this output pin 140 by way of transmission lines (180). The integrated circuit switches between the pin electronics and the high voltage buffer by putting the output stage of the non-active circuit into a high impedance mode as indicated by 160 when the high voltage buffer is desired and placing the high voltage buffer into a high impedance mode as indicated by 170 when the low voltage pin electronics 100 are desired.

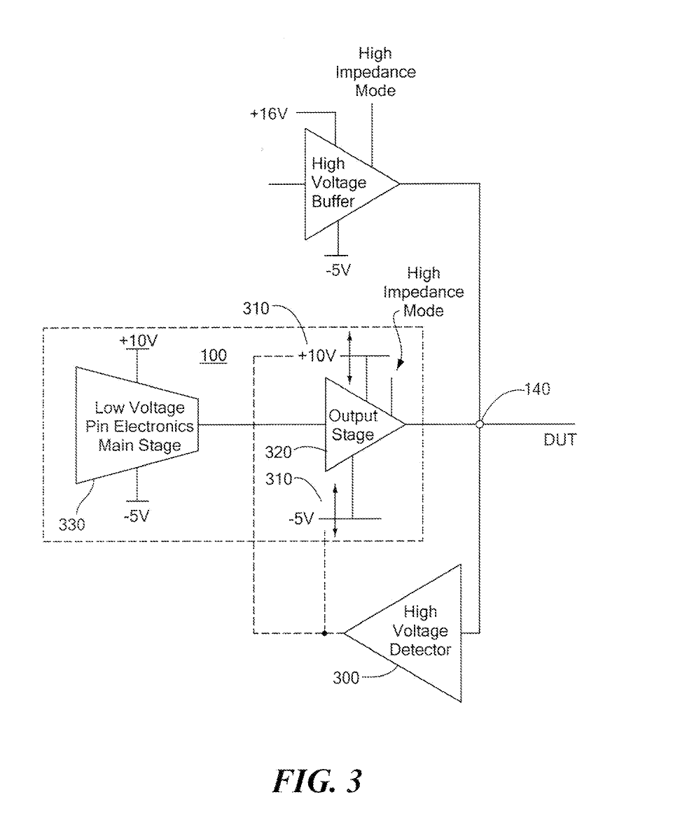

Since the voltage produced at the output pin by the high voltage buffer, PMU, or DUT can be above the supply rail voltage of the pin electronics, the supply rail voltages of the pin electronics may be adjusted upwards during high voltage operation in order to avoid destructive damage to the pin electronics which could be caused by applying high voltage signals to the low voltage (high speed) devices used to implement the pin electronics. FIG. 3 shows additional circuitry for adjusting the supply rail voltages. The pin electronics circuit 100 is split into a main pin electronics circuit 330 and an output stage 320. The supply rails to the main pin electronics circuit 330 and output stage 320 are decoupled. The supply rail voltages 310 of output stage 320 can be made to track with the voltage at output node 140 without interfering with the default supply rail voltages of the main pin electronics circuit 330.

The supply rail voltages 310 of output stage 320 are controlled by a high voltage detector 300. The high voltage detector 300 is coupled to the output pin 140. The high voltage detector 300 responds to the voltage on the output pin 140 in such a way as to lift the supply rails 310 of the pin electronics output stage 320 up as the voltage at the output pin 140 exceeds the otherwise safe operating limit of the low voltage pin electronics output stage 320. The high voltage detector 300 can be implemented as a simple buffer whose output rises in direct proportion to the voltage at its input, but has its lower limit output excursion clamped at the default supply rail voltages of the main low voltage pin electronics circuit 330. When the voltage at output node 140 does not exceed the ordinary safe operating limit of the pin electronics output stage 320, the high voltage detector 300 maintains the supply rail voltages at the default levels. When the voltage at output node 140 exceeds the ordinary safe operating limit of the pin electronics output stage 320, the high voltage detector 300 begins to increase the supply rail voltages 310 at least proportional to the voltage at the output pin 140. As a result, the voltages of the supply rails 310 to the pin electronics are always maintained at an appropriate level to support the respective voltage at output node 140 without causing destructive damage or malfunction to output stage 320. Thus, the supply rail voltage 310 is bootstrapped by the output voltage at node 140. By bootstrapping the supply rail voltage 310 in this way, the pin electronics 100 are not damaged by the high voltages produced at output node 140 by the high voltage buffer 120, PMU or DUT (not shown).

As previously mentioned, manufacturers of integrated circuits, and more specifically flash memory require that the transition between the low voltage levels of the pin electronics and the high voltage level of the high voltage buffer be both monotonic and slew rate limited. Because of this requirement, the slew rate of the high voltage detector 300 must be at or above the slew rate of the high voltage buffer in order to avoid damage to the output stage. In order to obtain a monotonic transition, the signal must avoid both overshoot and undershoot and a single pole or overdamped response is often desired.

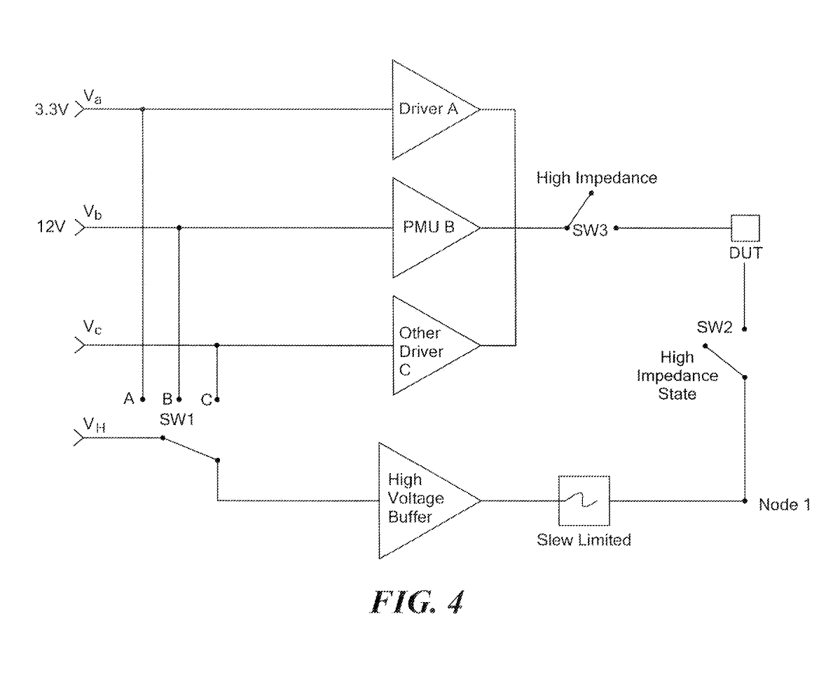

The circuit shown in FIG. 4 allows for the switching between a first input having a first voltage level and a second input having a second voltage level without any voltage glitches occurring at the DUT pin due to a sudden change in voltage states. Additionally, this circuit provides for monotonic transitions between voltages and prevents pre-shoot, overshoot and undershoot. A voltage buffer, which shall be referred to as a high voltage buffer, is used to slew the DUT pin voltage level from a first voltage level to a second voltage level prior to switching the input source to the second level. The second input is then switched into the circuit and the high voltage buffer is then disconnected from the circuit. Because the high voltage buffer is slew limited, the high voltage buffer safely conveys the voltage from the first voltage level to the second voltage level monotonically.

In the embodiment shown, there are four possible inputs: a driver voltage Va, PMU voltage Vb, a second driver voltage marked Vc, and a high voltage Vh. The circuit also includes four voltage signal generators: driver A, PMU B, other driver C, and high voltage buffer H. In addition, there are three switching elements (Sw1, Sw2, and Sw3). The switching elements are conceptual switches and may be embodied in any one of a number of ways known to those of ordinary skill in the art. For example, the switching elements may be actual complex switches, MOSFETs, or even circuitry that provides a high impedance mode in the output stage of the voltage signal generators. Sw1 switches the various input voltages to the slew limited high voltage buffer. The second switch, Sw2, connects the voltage signal generators to the DUT pin. The third switch couples the high voltage buffer to the DUT pin. Switches Sw2 and Sw3 include a high impedance voltage state Z. The high impedance voltage state Z disconnects the voltage signal generators (Z state Sw2) from the output pin or disconnects the high voltage buffer (Z state Sw3) from the output pin. Although Sw1 and Sw2 are shown as multi-pole switches, other switching mechanisms can be employed as are well known in the art. For example, each voltage signal generator may include a separate field effect transistor that acts as a switch. When all of the field effect transistors are in an off state, Sw2 is effectively in the high impedance state Z.

The circuit operates as follows. For example, if the desired change in voltage at the DUT input is between voltage level Va and voltage level Vb, Sw1 begins at position A, Sw2 begins at position A and Sw3 begins at position Z (high Z impedance state). In this initial state, node 1 is continually pre-charged to voltage level Va. Sw3 is then switched from the high impedance state, Z, to switch state D by closing the switch. Thus, the high voltage buffer is coupled to the DUT pin because the voltage at node 1 that has been pre-charged to voltage level A is equal to the voltage level at the DUT pin, the switching transient during this step will be minimized. Driver A can then be taken out of the circuit. To take driver A out of the circuit, Sw2 is switched to high impedance state Z. Thus, driver A is disconnected from the DUT, and only the high voltage buffer remains connected to the DUT. The voltage at the DUT pin has not changed as a result of node 1 being first pre-charged to a voltage substantially equal to Va.

Voltage level Vb is then connected to the input of the high voltage buffer. Sw1 switches between A and B. The voltage at the DUT gently slews at the slew rate of the high voltage buffer from voltage level Va to the voltage level Vb. The characteristic of the voltage transition from voltage level A to voltage level B is determined by the characteristic properties of the high voltage buffer. In some embodiments, voltage Va may be greater than voltage Vb; and in other embodiments, voltage Vb may be greater than voltage Va. After sufficient time has elapsed to guarantee that the voltage at the DUT pin has settled to Vb, then Sw2 is switched from Z to B, coupling the PMU driver to the DUT, which has already been charged up to a voltage substantially equal to Vb by the high voltage buffer. Sw3 is then switched from D back to the high impedance state Z. The high voltage buffer is thus disconnected from the DUT. The switches end in the states where Sw1 is switched to B, Sw2 is switched to B, and Sw3 is switched to Z. Thus, the high voltage buffer is used as a voltage conveyor allowing the voltages to transition smoothly between two states.

Similarly, the voltage conveyor can be used for transitioning between a first voltage level Va and a second high voltage level Vh wherein the second high voltage level Vh is not within the operational range of the pin electronics elements. The voltage level at the output is assumed to be at voltage level Va and the pin electronics/voltage signal generator is coupled to the output and the voltage conveyor is decoupled from the output. The voltage conveyor is then coupled to the output and receives voltage level Va at its input. The voltage signal generator is decoupled from the output and the voltage conveyor maintains the voltage at the output as voltage level Va. The voltage conveyor at its input is then controllably switched between voltage level Va and a high voltage level Vh. The voltage conveyor then causes the voltage level at the output to slew to the high voltage level Vh.

The system may include an automatic state machine, such as a control sequencer for providing control signals for controlling the switching elements.

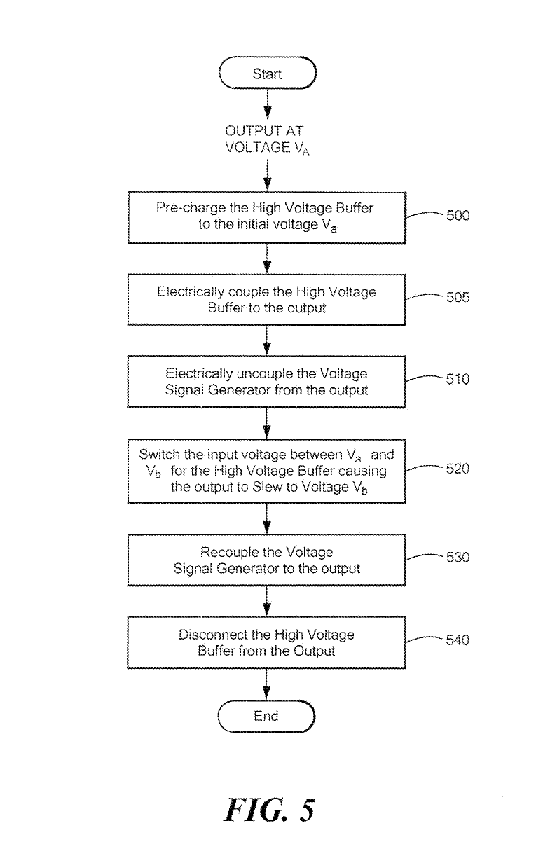

FIG. 5 provides a flow chart for switching between a first voltage level Va and a second voltage level Vb. The inclusion of the high voltage buffer as a part of the switching sequence may be appropriate when signal glitches are not desired and the input devices are not capable of providing a continuous voltage transition. Thus, the high voltage buffer slews the input signal from a first voltage level to a second voltage level. In this embodiment, the voltage at the output is assumed to be Va. First, the high voltage buffer is pre-charged to the initial value Va (500). Then it is connected to the output of the circuit (505). The voltage signal generator such as the driver, load, or comparator of the pin electronics are electrically uncoupled from the output (510) after the high voltage buffer is connected. This can be accomplished by switching to a high impedance state at the output of the voltage signal generator. The input voltage to the high voltage buffer is then switched between Va and Vb (520). This causes the high voltage buffer to slew from Va toward Vb and eventually produce Vb at the output pin. After sufficient time has elapsed, the desired voltage signal generator, such as a portion of the pin electronics are then electrically reconnected to the circuit and the output of the pin electronics is Vb, which is equivalent to the voltage at the output pin (530). The high voltage buffer is then electrically disconnected from the output (540). By including a slew limited high voltage buffer within the circuit that can be switched into and out of the circuit, the voltage levels can be changed monotonically between states without preshoot, overshoot, undershoot, or undesirable waveform aberrations.

Although various exemplary embodiments of the invention have been disclosed, it should be apparent to those skilled in the art that various changes and modifications can be made that will achieve some of the advantages of the invention without departing from the true scope of the invention. These and other obvious modifications are intended to be covered by the appended claims.

1. A system for changing voltage states at an output of an electronic device, the system comprising:
a first voltage source producing a first voltage;
a second voltage source producing a second voltage;
a voltage conveyor module controllably coupled to the output of the electronic device; and
a voltage signal generator controllably coupled to the output and capable of providing the first voltage to the output;
wherein when the voltage conveyor module is controllably coupled to the output, the voltage signal generator is controllably decoupled from the output, and the voltage conveyor module conveys the second voltage to the output in a characteristic manner.

2. The system according to claim 1 wherein the first and the second voltage sources are controllably coupled to the voltage signal generator.

3. The system according to claim 2 wherein the voltage signal generator is a pin electronics circuit.

4. The system according to claim 1, further comprising:
a second voltage signal generator controllably coupled to the output and capable of providing the second voltage to the output.

5. The system according to claim 1 wherein the voltage signal generator has an associated voltage range and wherein the first voltage is within the voltage range and the second voltage is not within the voltage range.

6. The system according to claim 1 wherein the voltage at the output transitions between the first and the second voltage without discontinuities.

7. The system according to claim 1, wherein the voltage at the output transitions monotonically between the first voltage and the second voltage.

8. The system according to claim 1, wherein the voltage at the output transitions in a slew rate limited manner.

9. The system according to claim 1, wherein the voltage conveyor module is slew rate limited.

10. The system according to claim 1, wherein the system is constructed on a single integrated circuit.

11. The system according to claim 1, wherein the voltage conveyor has a supply rail voltage that is greater in magnitude than a supply rail voltage of the voltage signal generator.

12. The system according to claim 11 further comprising:
a high voltage sensor sensing voltage at the output and when the voltage exceeds the supply rail voltage of the voltage signal generator increases the supply rail voltage of at least a portion of the voltage signal generator.

13. The system according to claim 1 wherein the voltage conveyor is controllably coupled to the output by producing a high impedance in a first state and a low impedance in a second state.

14. The system according to claim 13 wherein the voltage signal generator is controllably coupled to the output by producing a high impedance in a first state and a low impedance in a second state.

15. The system according to claim 1, wherein an input of the voltage conveyor is controllably connected to one of a plurality of voltages.

16-19. (canceled)

20. A method for switching between a first voltage level and a second voltage level at an output of a circuit, the method comprising:
providing voltage at the first voltage level through a first circuit to the output of the circuit;
providing the voltage at the first voltage level to the voltage buffer;
coupling a voltage buffer to the output of the circuit;
decoupling the first circuit from the output of the circuit; and
switching the voltage between the first voltage level and the second voltage level causing the voltage at the output to slew to the second voltage level through the voltage buffer.

21. The method according to claim 20, further comprising:
recoupling the first circuit to the output of the circuit, wherein the voltage is provided at the second voltage level through the first circuit to the output; and
decoupling the voltage buffer from the output.

22. The method according to claim 20, wherein the coupling, decoupling and switching are performed by an automatic sequencing circuit.
